(19) United States
(12) Patent Application Publication
(10) Pub. No.: US 2013/0125974 A1
(43) Pub. Date: May 23, 2013

(54) SOLAR CELL WITH METAL GRID FABRICATED BY ELECTROPLATING

(71) Applicant: Silevo, Inc., Fremont, CA (US)

(72) Inventors: Bob Wen Kong, Newark, CA (US); Jianming Fu, Palo Alto, CA (US)

(73) Assignee: SILEVO, INC., Fremont, CA (US)

(21) Appl. No.: 13/679,913

(22) Filed: Nov. 16, 2012

Related U.S. Application Data
(63) Continuation-in-part of application No. 12/835,670, filed on Jul. 13, 2010.
(60) Provisional application No. 61/334,579, filed on May 14, 2010.

(51) Int. Cl. H01L 31/0224; H01L 31/18

(52) U.S. Cl. CPC H01L 31/022433; H01L 31/18
USPC 136/256; 438/98

(57) ABSTRACT

One embodiment of the present invention provides a solar cell. The solar cell includes a photovoltaic structure, a transparent-conductive-oxide (TCO) layer situated above the photovoltaic structure, and a front-side metal grid situated above the TCO layer. The TCO layer is in contact with the front surface of the photovoltaic structure. The front-side metal grid includes a first metal layer comprising Cu, and a second metal layer covering a top surface and sidewalls of the first metal layer. The second metal layer comprises at least one of: Ag and Sn.

### RELATED APPLICATION

This application is a continuation-in-part application of U.S. patent application Ser. No. 12/835,670 (attorney docket number SSP10-1001US), entitled “SOLAR CELL WITH METAL GRID FABRICATED BY ELECTROPLATING,” by inventors Jianming Fu, Zheng Xu, Chentao Yu, and Jiunn Benjamin Heng, filed 13 Jul. 2010, which claims the benefit of U.S. Provisional Application No. 61/334,579, Attorney Docket Number SSP10-1001PSP, entitled “SOLAR CELL WITH METAL GRIDS FABRICATED BY USING ELECTROPLATING,” by inventors Jianming Fu, Zheng Xu, Chentao Yu, and Jiunn Benjamin Heng, filed 14 May 2010.

### BACKGROUND

1. Field

This disclosure is generally related to designing of solar cells. More specifically, this disclosure is related to a solar cell that includes a metal grid fabricated by an electroplating technique.

2. Related Art

The negative environmental impact caused by the use of fossil fuels and their rising cost have resulted in a dire need for cleaner, cheaper alternative energy sources. Among different forms of alternative energy sources, solar power has been favored for its cleanness and wide availability.

A solar cell converts light into electricity using the photovoltaic effect. There are several basic solar cell structures, including a single p-n junction solar cell, a solar cell, and a multi-junction solar cell. A typical single p-n junction structure includes a p-type doped layer and an n-type doped layer. Solar cells with a single p-n junction can be homojunction solar cells or heterojunction solar cells. If both the p-doped and n-doped layers are made of similar materials (materials with equal bandgaps), the solar cell is called a homojunction solar cell. In contrast, a heterojunction solar cell includes at least two layers of materials of different bandgaps. A p-i-n/n-i-p structure includes a p-type doped layer, an n-type doped layer, and an intrinsic (undoped) semiconductor layer (the i-layer) sandwiched between the p-layer and the n-layer. A multi-junction structure includes multiple single-junction structures of different bandgaps stacked on top of one another.

In a solar cell, light is absorbed near the p-n junction, generating carriers. The carriers diffuse into the p-n junction and are separated by the built-in electric field, thus producing an electrical current across the device and external circuitry. An important metric in determining a solar cell's quality is its energy-conversion efficiency, which is defined as the ratio between power converted (from absorbed light to electrical energy) and power collected when the solar cell is connected to an electrical circuit.

FIG. 1 presents a diagram illustrating an exemplary homojunction solar cell based on a crystalline-Si (c-Si) substrate (prior art). Solar cell 100 includes a front-side Ag electrode grid 102, an anti-reflection layer 104, a c-Si based emitter layer 106, a p-type c-Si substrate 108, and an aluminum (Al) back-side electrode 110. Arrows in FIG. 1 indicate incident sunlight.

In conventional c-Si based solar cells, the current is collected by front-side Ag grid 102. To form Ag grid 102, conventional methods involve printing Ag paste onto the wafers and then firing the Ag paste at a temperature between 700° C. and 800° C. The high-temperature firing of the Ag paste ensures good contact between Ag and Si, and low resistivity of the Ag lines.

Many newly developed solar cells are based on amorphous Si (a-Si), which can be used to form a heterojunction with the c-Si layer, or to provide surface passivation for the emitter. The existence of an a-Si layer prevents the solar cell from undergoing high-temperature firing of the Ag paste. To avoid the crystallization of the a-Si layer, and to maintain the passivation effect, the metallization temperature needs to be less than 200° C. One approach is to apply low-temperature Ag paste, which can be cured at a temperature below 200° C. However, the resistivity of the Ag paste cured at the low temperature is usually five to ten times higher than the one cured at a higher temperature. Hence, such an approach can result in high series resistance of the Ag grid which, in turn, results in lower solar cell efficiency. Printing the Ag grid with larger cross sections (thicker Ag layer) can decrease the series resistance. However, such an approach requires multiple printing steps, thus not only adding production complexity, but also requiring the consumption of a larger amount of Ag, which is expensive.

### SUMMARY

One embodiment of the present invention provides a solar cell. The solar cell includes a photovoltaic structure, a transparent-conductive-oxide (TCO) layer situated above the photovoltaic structure, and a front-side metal grid situated above the TCO layer. The TCO layer is in contact with the front surface of the photovoltaic structure. The front-side metal grid includes a first metal layer comprising Cu, and a second metal layer covering a top surface and sidewalk of the first metal layer. The second metal layer comprises at least one of: Ag and Sn.

In a variation on the embodiment, the resistivity of the front-side metal layer is less than 2×10⁻⁵ Ω·cm.

In a variation on the embodiment, the first metal layer is formed using an electroplating process.

In a variation on the embodiment, the second metal layer is formed using a metal immersion process.

In a further variation, the metal immersion process is conducted in an acidic environment, thereby preventing deposition of the second metal layer on the TCO layer.

In a further variation, the metal immersion process involves a complexing agent that comprises Thiourea.

In a variation on this embodiment, the solar cell further includes a back-side TCO layer situated on the back side of the photovoltaic structure and a back-side metal grid situated on the back-side TCO layer. The back-side TCO layer is in contact with the back surface of the photovoltaic structure. The back-side metal grid includes an inner metal core comprising at least one of Cu and Ni, and an outer metal layer covering a top surface and sidewalk of the inner metal core. The outer metal layer comprises at least one of: Ag and Sn.

### BRIEF DESCRIPTION OF THE FIGURES

FIG. 1 presents a diagram illustrating an exemplary homojunction solar cell based on a crystalline-Si substrate (prior art).

FIG. 2 presents a diagram illustrating an exemplary process of fabricating a solar cell in accordance with an embodiment of the present invention. 2A illustrates a Si substrate. 2B illustrates a silicon oxide layer grown on top of the Si substrate and an amorphous Si (a-Si) layer deposited on the silicon oxide layer. 2C illustrates a transparent-conducting-oxide (TCO) layer deposited on the a-Si layer. 2D illustrates a patterned mask deposited on the TCO layer, 2E illustrates metals being deposited at the openings of the mask layer. 2F illustrates the mask layer being removed. 2G illustrates the top view of an exemplary front-side electrode grid. 2H illustrates a back-side oxide layer, a back-side a-Si layer, a back-side TCO layer, and a back-side electrode grid formed on the backside of the Si substrate.

FIG. 3 presents a diagram illustrating an exemplary process of fabricating a solar cell in accordance with an embodiment of the present invention. 3A illustrates a Si substrate. 3B illustrates a silicon oxide layer grown on top of the Si substrate and an amorphous Si (a-Si) layer deposited on the silicon oxide layer. 3C illustrates a transparent-conducting-oxide (TCO) layer deposited on the a-Si layer. 3D illustrates a thin metal layer deposited on the TCO layer. 3E illustrates a patterned mask deposited on top of the thin metal layer. 3F illustrates one or more layers of metals deposited at the openings of the mask layer. 3G illustrates a metal grid formed after the making layer and portions of the thin metal layer being removed. 3H illustrates a protective metal layer deposited on the metal grid. 31 illustrates a back-side oxide layer, a back-side a-Si layer, a back-side TCO layer, a back-side adhesive metal layer, a back-side metal grid, and a back-side protective metal layer formed on the backside of the Si substrate.

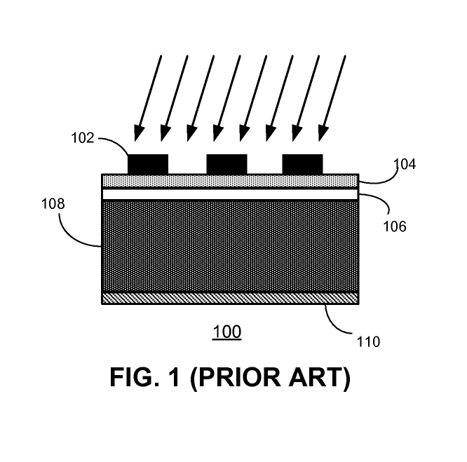

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Embodiments of the present invention provide a solar cell that includes a metal grid formed by electroplating. The solar includes an n-type crystalline-Si (c-Si) substrate, an amorphous-Si (a-Si) layer stack including a p-type doped emitter layer and a passivation layer, a transparent-conductive-oxide (TCO) layer, and front- and back-side electrode metal grids. The front-side metal grid is formed by electroplating a metal stack, which can be a single-layer or a multi-layer structure. The back-side electrode is formed by screen-printing, electroplating, or aerosol-jet printing of a metal grid.

### Fabrication Process

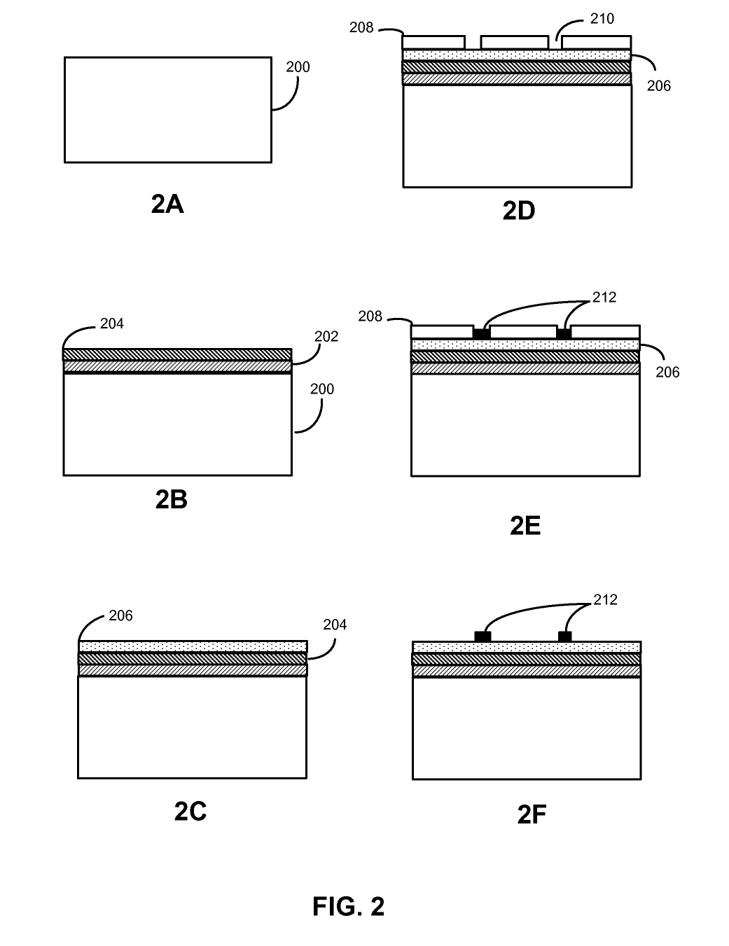

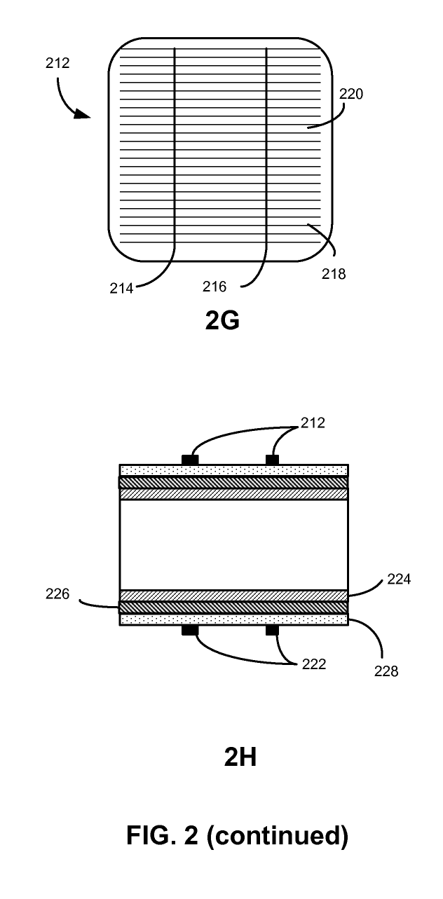

FIG. 2 presents a diagram illustrating an exemplary process of fabricating a solar cell in accordance with an embodiment of the present invention.

In operation 2A, a Si substrate 200 is prepared. In one embodiment, Si substrate 200 can be a crystalline-Si (c-Si) substrate.

In operation 2B, a silicon oxide layer 202 is grown on c-Si substrate 200 to form a passivation layer, and an amorphous Si (a-Si) layer 204 with graded doping is deposited on silicon oxide layer 202 to form an emitter. Depending on the doping type of c-Si substrate 200s, a-Si layer 204 can be either n-type doped or p-type doped. In one embodiment, part of the front a-Si layer 204 is heavily doped with p-type dopants. The highest doping concentration of can be between 1×10¹⁷/cm³ and 1×10²⁰/cm³. The thickness of a-Si layer 204 can be between 10 nm and 50 nm, and the thickness of oxide layer 202 can be between 0.5 nm and 2 nm. These form a tunneling junction as carriers tunnel through the thin oxide. Amorphous-Si layer 204 can be deposited using plasma-enhanced chemical vapor deposition (PECVD). Even though a-Si layer 204 has higher absorption coefficient due to its direct band gap, because the thickness of a-Si layer 204 can be much smaller compared with that of the emitter layer in a homojunction solar cell, the absorption of short wavelength light is significantly reduced, thus leading to higher solar cell efficiency. Note that Si substrate 200, oxide layer 202, and a-Si 204 make up the basic building blocks of a photovoltaic structure. Depending on the material selected to form the different layers, the photovoltaic structure can include at least one of: a homogeneous junction, a heterojunction, a tunneling junction, or multiple p-n junctions.

In operation 2C, a layer of transparent-conductive-oxide (TCO) is deposited on top of a-Si layer 204 to form an anti-reflection layer 206 and electrical conduction layer for collecting current. Examples of TCO include, but are not limited to: indium-tin-oxide (ITO), aluminum-doped zinc-oxide (ZnO:Al), gallium-doped zinc-oxide (ZnO:Ga), tungsten-doped indium oxide (IWO), and a Zn-in-Sn—O (ZITO). Techniques used for forming anti-reflection layer 206 include, but are not limited to: PECVD, sputtering, and e-beam evaporation. In addition to depositing a layer of TCO material on the front side of the wafer as TCO layer 206, it is also possible to deposit a TCO layer on both sides of the wafer. In one embodiment, a TCO layer is deposited on the front side, the back side, and the vertical bevel on the edge of the wafer.

In operation 2D, a patterned masking layer 208 is deposited on top of TCO layer 206. The openings of masking layer 208, such as opening 210, correspond to the locations of a designed front metal grid. Masking layer 208 can include a patterned photo resist layer, which can be formed using a photolithography technique. In one embodiment, the photo resist layer is formed by screen-printing resist on top of the wafer. The photo resist is then baked to remove solvent. A mask is laid on the photo resist, and the wafer is exposed to UV light. After the UV exposure, the mask is removed, and the photo resist is developed in a photo resist developer. Opening 210 is formed after develop. The photo resist can also be applied by spraying, dip coating, or curtain coating. Dry film resist can also be used. Alternatively, masking layer 208 can include a layer of patterned silicon oxide (SiO₂). In one embodiment, masking layer 208 is formed by first depositing a layer of SiO₂ using a low-temperature plasma-enhanced chemical-vapor-deposition (PECVD) technique. In a further embodiment, masking layer 208 is formed by dip-coating the front surface of the wafer using silica slurry, followed by screen-printing an etchant that includes hydrofluoric acid or fluorides. Other masking materials are also possible, as long as the masking material is electrically insulating.

In operation 2E, one or more layers of metals are deposited at the openings of masking layer 208 to form a metal grid 212. Metal grid 212 can be formed using an electroplating technique, which can include electrodeposition and/or electroless deposition. In one embodiment, TCO layer 206 is coupled to the cathode of the plating power supply, which can be a direct current (DC) power supply, via an electrode, TCO layer 206 and masking layer 208, which includes the openings, are submerged in an electrolyte solution which permits the flow of electricity. Note that, because only the openings within masking layer 208 are electrically conductive, metals will be selectively deposited into the openings, thus forming a metal grid with a designed pattern. Metal grid 212 can be a single layer structure, such as a single layer of Cu or Ag; or a multilayer structure, such as a Ni/Cu bi-layer structure, a Cu/Sn bi-layer structure, a Ni/Cu/Sn tri-layer structure, and a Ni/Cu/Ag tri-layer structure. The sidewalk and top of metal grid 212 can also be coated with Ag or Sri. When a layer of Cu is deposited, a Cu plate or a basket of copper chunks is used at the anode, and the solar cell is submerged in the electrolyte suitable for Cu plating. The current used for Cu plating is between 0.1 Ampere and 2 Ampere for a wafer with a dimension of 125 mm×125 mm, and the thickness of the Cu layer is approximately tens of micrometers. Other parameters may be used for wafers with different dimensions. The deposition of a Ni layer can also be an electroplating process, during which a Ni plate is used at the anode, and the solar cell is submerged in the electrolyte suitable for Ni plating. The voltage used for Ni plating can be between 1 V and 3 V. In cases where the back side of the wafer is also covered with a layer of TCO, the cathode of the plating power supply can be coupled to the TCO layer on the back side of the wafer, and the whole wafer is submerged in the electrolyte solution. The cathode can also be directly in contact with the front side by using contact pins at the openings of masking layer 208. Metal stacks deposited using the electroplating technique often have lower resistivity compared with low-temperature-cured silver paste layers. In one embodiment, the resistivity of metal grid 212 is less than 2×10⁻⁵ Ω·cm. In contrast, Ag paste cured at 200° C. often has a resistivity greater than 2×10⁻⁵ Ω·cm. The lower resistivity of the metal grid can significantly enhance solar cell efficiency.

In operation 2F, masking layer 208 is removed. As a result, front-side electrode grid (metal grid) 212 is completed with the designed pattern and line width. FIG. 2G illustrates the top view of an exemplary front-side electrode grid 212 in accordance with an embodiment of the present invention. Front-side electrode grid 212 includes busbars, such as busbars 214 and 216, and fingers, such as fingers 218 and 220. Busbars are thicker metal strips connected directly to the external leads, and fingers are finer metal strips that collect current for delivery to the busbars.

In operation 2H, back-side oxide layer 224, back-side a-Si layer 226, and back-side TCO layer 228 are formed using the methods described in operation 2A through 2C. In addition, backside electrode grid 222 is formed on the hack-side TCO layer 228. Back-side electrode grid 222 can be formed using the same electroplating method as the one used for forming front-side electrode grid 212. The backside grid could be different from front side in densities, or in blanket.

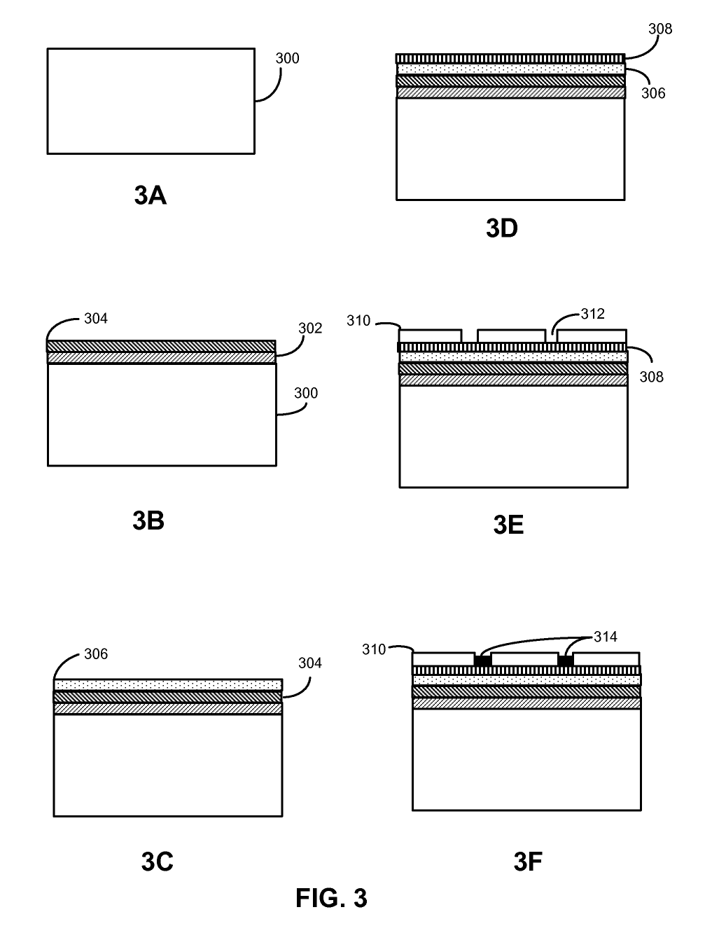

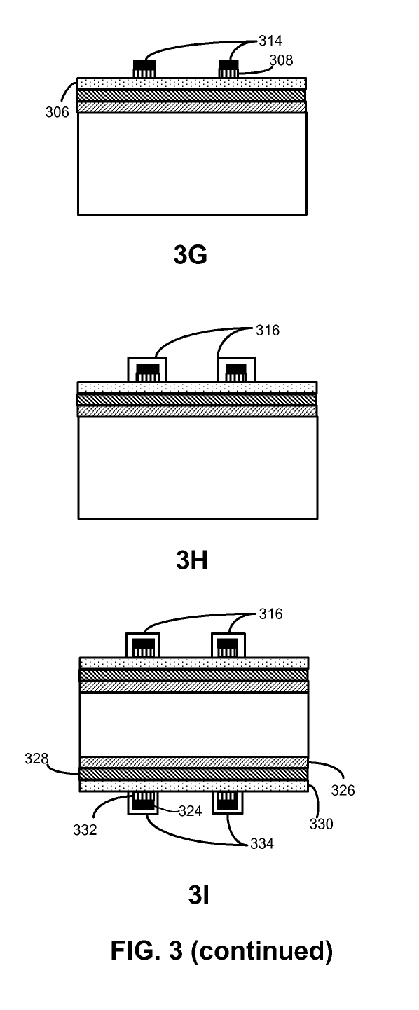

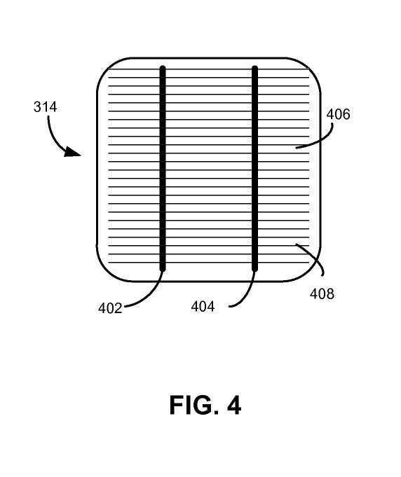

FIG. 3 presents a diagram illustrating another exemplary process of fabricating a solar cell in accordance with an embodiment of the present invention.

In operation 3A, a Si substrate 300 is prepared. The process used for preparing Si substrate 300 is similar to the one used in operation 2A.

In operation 3B, an oxide layer 302 is grown on Si substrate 300 to form a passivation layer, and an a-Si layer 304 with graded doping is deposited on oxide layer 302 to form an emitter. The deposition technique used for depositing layers 304 and 302 is similar to the one used in operation 2B.

In operation 3C, a layer of TCO material is deposited on top of a-Si layer 304 to form an anti-refection layer 306. The formation process of anti-reflection layer (or TCO layer) 306 is similar to the one used in operation 2C.

In operation 3D, a thin metal layer 308 is deposited on top of TCO layer 306. Thin metal layer 308 can be deposited using a physical vapor deposition (PVD) technique, such as sputtering deposition or evaporation. Thin metal layer 308 can include Cu, Ni, Ag, NiV, Ti, Ta, W, TiN, TaN, WN, TiW, NiCr, and their combinations. Thin metal layer 308 can also be a metal stack that includes a layer of one or more of the aforementioned metals directly deposited on TCO layer 306 and a layer of subsequently deposited copper (so-called the seed layer). The thickness of the copper seed layer can be between 20 nm and 500 nm. Forming thin metal layer 308 on top of TCO layer 306 improves the adhesion between TCO layer 306 and the subsequently deposited front-side metal grid.

In operation 3E, a patterned masking layer 310 is deposited on top of thin-metal layer 308 using a process similar to the one used in operation 2D. The openings of masking layer 310, such as opening 312, correspond to the locations of a designed front-side metal grid.

In operation 3F, one or more layers of metals are deposited at the openings of masking layer 310 to form a metal grid 314 using materials and processes similar to the ones used in operation 2E. In one embodiment, a electroplating process is used to deposit a Cu grid 314.

In operation 3G, masking layer 310 and portions of thin metal layer 308 are removed to expose the portions of TCO layer 306 not covered by metal grid 314. As a result, metal grid 314 is completed with the designed pattern and line width. If thin metal layer 308 is transparent, then operation 3G can only remove masking layer 310. In one embodiment, thin metal layer 308 includes an ultrathin NiCr layer, which is transparent and remains intact after operation 3G.

In operation 3H, a protective metal layer 316 is deposited on metal grid 314, covering the top and sidewalk of metal grid 314 and optionally the sidewalls of thin metal layer 308. In one embodiment, protective metal layer 316 includes, but is not limited to: Sn and Ag. Note that by covering the entire surface of metal grid 314, including the sidewalls, protective metal layer 316 prevents metal grid 314 from oxidation. In addition, protective metal layer 316 provides solderbility to the busbars, making it possible for subsequent tabbing process. Because TCO layer 306 is electrically conductive, the electroplating process is no longer an option for depositing protective metal layer 316. In one embodiment, protective layer 316 is deposited using a metal immersion process. During fabrication, the solar cell is immersed in a solution that includes metal ions, such as Sn and Ag ions. A displacement reaction occurs between the metal ions in the solution and the surface metal of metal grid 314. For Cu-based metal grid 314, the Sn or Ag ions in the solution displaced Cu ions on the top and sidewalls of metal grid 314. As a result, a layer of Sn or Ag covers the top and sidewalls of metal grid 314 completely.

Note that in order for the displacement reaction to occur, the metal ions in the solution need to have a higher redox potential than that of the metal to be displaced. This is different from electroplating and the electroless plating processes. The electroplating process takes place under current, and the electroless plating process requires a reducing agent to reduce the metal ions in the solution to the plated metal.

Because the redox potential of Cu is greater than that of Sn, deposition of Sn on the surface of a Cu grid by immersion cannot be driven by potential differences as a normal displacement reaction. Instead, a complexing agent, such as Thiourea (SC(NH₂)₂) and its derivants (or derivatives), can be used to alter the reverse potential for the displacement reaction, thus allowing the reaction to take place. More specifically, Thiourea reduces the redox potential of Cu from +0.34 V to −0.39 V, comparing with the redox potential of Sn at −0.14 V. The Cu ions can then replace the Sn ions from the salt solution. The displacement reaction can be expressed as:

2Cu+Sn⁺⁺+4SC(NH₂)₂→2Cu⁺+4SC(NH₂)₂+Sn.

In one embodiment, the chemical solution used for immersion plating of Sn includes, but not limited to: Sn salt for providing Sn ions, Thiourea or its derivants used as a complexing agent, acid (such as H₂SO₄) for keeping an acidic environment to prevent deposition of Sn on TCO layer 306, accelerator, stabilizer, and surfactant. In addition to immersion plating of Sn, immersion plating of Ag can also be performed, either by applying a separate immersion plating to form an additional layer of coating, or by mixing Sn and Ag ions in the chemical solution to achieve simultaneous Sn and Ag coating.

In operation 3I, back-side oxide layer 326, back-side a-Si layer 328, back-side TCO layer 330, adhesive metal layer 332, back-side metal grid 324, and back-side protective metal layer 334 are formed on the back side of the wafer using a process that is similar to the one used in operations 3B through 3G.

FIG. 4 illustrates an exemplary top view of front-side electrode grid 314 in accordance with an embodiment of the present invention. Front-side electrode grid 314 includes busbars, such as busbars 402 and 404, and fingers, such as fingers 406 and 408. Busbars are thicker metal strips connected directly to the external leads, and fingers are finer metal strips that collect current for delivery to the busbars.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

What is claimed is:

1. A solar cell, comprising:
a photovoltaic structure;
a transparent-conductive-oxide (TCO) layer situated above the photovoltaic structure, wherein the TCO layer is in contact with the front surface of the photovoltaic structure; and
a front-side metal grid situated above the TCO layer, wherein the front-side metal grid includes:
a first metal layer comprising Cu, and
a second metal layer covering a top surface and sidewalk of the first metal layer, wherein the second metal layer comprises at least one of: Ag and Sn.

2. The solar cell of claim 1, wherein the resistivity of the front-side metal grid is less than 2×10⁻⁵ Ω·cm.

3. The solar cell of claim 1, wherein the first metal layer is formed using an electroplating process.

4. The solar cell of claim 1, wherein the second metal layer is formed using a metal immersion process.

5. The solar cell of claim 4, wherein the metal immersion process is conducted in an acidic environment, thereby preventing deposition of the second metal layer on the TCO layer.

6. The solar cell of claim 4, wherein the metal immersion process involves a complexing agent that comprises Thiourea.

7. The solar cell of claim 1, further comprising:
a back-side TCO layer situated on the back side of the photovoltaic structure, wherein the back-side TCO layer is in contact with the back surface of the photovoltaic structure; and
a back-side metal grid situated on the back-side TCO layer, wherein the back-side metal, grid includes:
an inner metal core comprising Cu, and
an outer metal layer covering a top surface and sidewalls of the inner metal core, wherein the outer metal layer comprises at least one of: Ag and Sn.

8. A method for fabricating a solar cell, comprising:
depositing one or more layers of amorphous-Si (a-Si) on top of a crystalline Si (c-Si) substrate with thin oxide formed on the surface to form a photovoltaic structure;
depositing a layer of transparent-conductive-oxide (TCO) on top of the a-Si layers;
forming a front-side electrode grid comprising a metal stack on top of the TCO layer, wherein the metal stack includes:
a first metal layer comprising Cu, and
a second metal layer covering a top surface and sidewalls of the first metal layer, wherein the second metal layer comprises at least one of: Ag and Sn; and
forming a back-side electrode on the back side of the Si substrate.

9. The method of claim 8, wherein the resistivity of the front-side electrode grid is less than 2×10⁻⁵ Ω·cm.

10. The method of claim 8, wherein forming the first metal layer involves electroplating the first metal layer on top of the TCO layer.

11. The method of claim 10, wherein forming the first metal layer further involves depositing and/or removing a patterned masking layer on top of the TCO.

12. The method of claim 8, wherein forming the second metal layer involves a metal immersion process.

13. The method of claim 12, wherein the metal immersion process is conducted in an acidic environment, thereby preventing deposition of the second metal layer on the TCO layer.

14. The method of claim 12, wherein the metal immersion process involves a complexing agent that comprises Thiourea.

15. The method of claim 8, further comprising:
depositing a back-side TCO layer on the back side of the photovoltaic structure, wherein the back-side TCO layer is in contact with the back surface of the photovoltaic structure; and
fabricating a back-side electrode grid on the back-side TCO layer, wherein the back-side electrode grid includes:
an inner metal core comprising Cu, and
an outer metal layer covering a top surface and sidewalk of the inner metal core, wherein the outer metal layer comprises at least one of: Ag and Sn.
